(19) United States
(12) Patent Application Publication
(10) Pub. No.: US 2005/0206465 A1
(43) Pub. Date: Sep. 22, 2005

(54) Voltage control oscillator

(75) Inventor: Fuyuki Okamoto, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION

(21) Appl. No.: 11/081,618

(22) Filed: Mar. 17, 2005

(30) Foreign Application Priority Data
Mar. 19, 2004 (JP) 2004-079734

(51) Int. Cl. H03B 5/00

(52) U.S. Cl. 331/177 V

(57) ABSTRACT

An LC circuit including an inductor and a pair of varactor elements is provided in an LC-VCO. This LC circuit outputs complementary alternating current signals from a pair of output terminals. The varactor element is formed by providing a gate electrode on an N well. Then, the well terminals of the varactor elements are connected to the respective output terminals, and the gate terminals of the varactor elements are connected to a control terminal. Thereby, as a control voltage to be applied to the control terminal becomes higher, the capacitance of the varactor element increases, and the frequency of the alternating current signal lowers.

### BACKGROUND OF THE INVENTION

1. Technical Field of the Invention

The present invention relates to a voltage control oscillator using resonance of an LC circuit including varactor elements and an inductor, and more specifically, a voltage control oscillator including varactor elements as variable capacitors which changes its capacitance according to a voltage to be applied. The voltage control oscillator according to the present invention can be used as a local oscillator or the like of a phase locked loop circuit.

2. Description of the Related Art

Recently, as a local oscillator (LO) of a phase locked loop (PLL) circuit used for the purpose of frequency multiplication and phase synchronization, a voltage control oscillator (LC-VCO) using resonance of a parallel LC circuit is employed. In this LC-VCO, a parallel LC circuit is formed by connecting an inductor and variable capacitors in parallel to each other, and by resonance of this parallel LC circuit, an alternating current signal with a frequency of a resonance frequency is oscillated. The resonance frequency is a frequency which makes the impedance of the parallel LC circuit infinite, and the resonance is a phenomenon in that a current flows alternately to the inductor and the variable capacitor in the parallel LC circuit.

When the inductance of the inductor is defined as L and the capacitance of the variable capacitor is defined as C, the resonance frequency f is calculated by the following numerical formula 1. It is understood that the resonance frequency f is reduced by increasing the capacitance C of the variable capacitor according to the following numerical formula 1.

$$f = \frac{1}{2 π \sqrt{LC}} \qquad ( 1 )$$

For example, as disclosed in the document “Salvatore Levantino and et. al., “Frequency Dependence on Bias Current in 5-GHz CMOS VCOs: Impact on Tuning Range and Flicker Noise Upconversion” IEEE Journal of Solid-State Circuits, August 2002, Vol. 37, No. 8, p. 1003-1011,” for the variable capacitor, a varactor element or the like is used, and its capacitance changes according to a control voltage to be applied. The varactor element has an advantage in that it can be formed by using the process of forming the MOSFET (Metal-Oxide Semiconductor Field Effect Transistor) when forming an LC-VCO in a semiconductor integrated circuit. FIG. 1 is a circuit diagram showing a conventional LC-VCO, and FIG. 2 is a sectional view showing the varactor element shown in FIG. 1. The conventional LC-VCO 101 shown in FIG. 1 is formed as an integrated circuit on the surface of the P type silicon substrate 12 shown in FIG. 2.

As shown in FIG. 1, this conventional LC-VCO 101 is connected to a power supply potential wiring VDD and a ground potential wiring GND. In the LC-VCO 101, the source of the P type transistor 2 is connected to the power supply potential wiring VDD, and the drain of the P type transistor 2 is connected to the drain of the N type transistor 4, and the source of the N type transistor 4 is connected to the ground potential wiring GND. The connecting point between the P type transistor 2 and the N type transistor 4 is formed into an output terminal 6. The source of the P type transistor 3 is connected to the power supply potential wiring VDD, the drain of the P type transistor 3 is connected to the drain of the N type transistor 5, and the source of the N type transistor 5 is connected to the ground potential wiring GND. The connecting point between the P type transistor 3 and the N type transistor 5 is formed into an output terminal 7.

Thereby, between the power supply potential wiring VDD and the ground potential wiring GND, a circuit including the P type transistor 2, the output terminal 6, and the N type transistor 4 connected in series and a circuit including the P-type transistor 3, the output terminal-7, and-the N type transistor 5 connected in series are connected in parallel to each other. Furthermore, the gate of the P type transistor 2 and the gate of the N type transistor 4 are connected to the output terminal 7, and the gate of the P type transistor 3 and the gate of the N type transistor 5 are connected to the output terminal 6.

Between the output terminal 6 and the output terminal 7, an inductor 8 is connected. Between the output terminal 6 and the output terminal 7, varactor elements 9 and 10 as variable capacitors are connected in series. Namely, between the output terminal 6 and the output terminal 7, a circuit including the varactor elements 9 and 10 connected in series and the inductor 8 are connected in parallel to each other. The varactor elements 9 and 10 are MOS type varactor elements. Therefore, in FIG. 1, the varactor elements 9 and 10 are indicated by using the symbols of PMOS transistors. The connecting point between the varactor element 9 and the varactor element 10 is formed into a control terminal 11 to which a control voltage VC is applied. An LC circuit is formed by the inductor 8 and the varactor elements 9 and 10.

As shown in FIG. 2, in the varactor element 9, an N well 13 is formed on the surface of the P type silicon substrate 12, and on the surface of the N well 13, N type diffusion regions 14 and 15 are formed apart from each other. At least in the region immediately above the region between the N type diffusion region 14 and the N type diffusion region 15 above-the N-well 13, a gate insulating film 16 made of, for example, silicon oxide is formed, and on this gate insulating film 16, a gate electrode 17 made of, for example, polysilicon is provided. The N type diffusion regions 14 and 15 are connected to the well terminals 18. The potentials of the well terminals 18 are defined as a well potential VW. The gate electrode 17 is connected to the gate terminal 19. The potential of the gate electrode 19 is defined as a gate potential VG. In the varactor element 9, a capacitor is formed between the gate electrode 17 and the N well 13. The construction of the varactor element 10 is the same as that of the varactor element 9.

The N well 13 is formed simultaneously with the N well of the PMOS transistor formed in another region of the integrated circuit including this LC-VCO 101, and the N type diffusion regions 14 and 15 are formed simultaneously with the source-drain region of the NMOS transistor, and the gate insulating film 16 and the gate electrode 17 are formed simultaneously with the gate insulating film and the gate electrode of the PMOS transistor or the NMOS transistor, respectively.

As shown in FIG. 1, in the conventional LC-VCO 101, the gate electrodes 19 of the varactor elements 9 and 10 are connected to the output terminals 6 and 7, respectively, and the well terminals 18 of the varactor elements 9 and 10 are connected to the control terminal 11.

Next, the operations of this conventional LC-VCO 101 are described. FIG. 3 is a graph showing the characteristics of the varactor element in which the horizontal axis shows the voltage to be applied to the varactor element and the vertical axis shows the capacitance of this varactor element, and FIG. 4 is a graph showing frequency characteristics of the LC-VCO in which the horizontal axis shows the voltage to be applied to the varactor element and the vertical axis shows the oscillating frequency of signals outputted from the pair of output terminals.

For example, when a certain electrical stimulus is applied to the LC circuit including the inductor 8 and the varactor elements 9 and 10 upon connecting the LC-VCO 101 to the power supply potential wiring VCC and the ground potential wiring GND, alternating current signals with a frequency that is the resonance frequency of this LC circuit are oscillated from the output terminals 6 and 7. In this case, signals outputted from the output terminals 6 and 7 are complementary signals.

However, by only the LC circuit, the currents are lost due to parasitic resistances, and oscillation stops soon. Therefore, a positive power supply potential is applied to the power supply potential wiring VDD and a ground potential is applied to the ground potential wiring GND, and P type transistors 2 and 3 and N type transistors 4 and 5 are provided, whereby the LC circuit is supplied with the power supply potential and the ground potential in synch with oscillation of the LC circuit to make the LC circuit to oscillate a resonance wave permanently.

For example, when the potential of the output terminal 6 goes low and the potential of the output terminal 7 goes high, the P type transistor 2 is turned off and the N type transistor 4 is turned on. As a result, the ground potential is applied to the output terminal 6. Furthermore, since the P type transistor 3 is turned on and the N type transistor 5 is turned off, the power supply potential is applied to the output terminal 7. Likewise, when the potential of the output terminal 6 goes high and the potential of the output terminal 7 goes low, the power supply potential is applied to the output terminal 6 and the ground potential is applied to the output terminal 7. Thus, when the potentials of the output terminals 6 and 7 go low or high according to operations of the P type transistors 2 and 3 and the N type transistors 4 and 5, the ground potential or the power supply potential can be applied to these output terminals, so that alternating current signals outputted from the output terminals 6 and 7 are continued without attenuating.

At this point, by changing the control voltage VC to be applied to the control terminal 11, the voltage (VG−VW) to be applied to the varactor elements 9 and 10 can be changed. Namely, since the control voltage VC becomes equal to the well potential VW, when the control voltage VC increases, the voltage (VG−VW) lowers. Namely, the relationship between the control voltage VC and the voltage (VG−VW) is a direct function with a negative gradient. Then, by changing the voltage (VG−VW), the capacitance of the varactor elements 9 and 10 can be changed.

As shown in FIG. 2 and FIG. 3, when the voltage (VG−VW) to be applied to the varactor elements 9 and 10, that is, the gate potential VG with respect to the well potential VW is increased to be sufficiently high, electrons as carriers gather at a region immediately under the gate electrode 17 on the surface of the N well 13, and this region becomes conductive, so that the thickness of the insulating layer between the gate electrode 17 and the N well 13 becomes equal to the film thickness of the gate insulating film 16 and the capacitance C between the gate electrode 17 and the N well 13 becomes maximum. Even if the voltage (VG−VW) is made higher than this, the thickness of the insulating layer between the gate electrode 17 and the N well 13 does not change, so that the capacitance C does not change, either.

When the control voltage VC is lowered from this state, the voltage (VG−VW) lowers, a depleted layer grows immediately under the gate insulating film 16 on the surface of the N well 13, and the thickness of the insulating layer between the gate electrode 17 and the N well 13 becomes a value resulting by adding the depth of the depleted layer to the film thickness of the gate insulating film 16, so that the capacitance C lowers. Then, when the voltage (VG−VW) becomes sufficiently low, the depleted layer does not become deeper than this, so that the capacitance also becomes stable.

Thus, when the voltage (VG−VW) increases, the capacitance C also increases. This state is referred to as positive correlation between the voltage (VG−VW) and the capacitance C, hereinafter. The rate of this increase is not even, and when the voltage (VG−VW) is in a predetermined range, the increasing rate is high, the graph becomes steep, and on both sides of this range, the increasing rate is small and the graph becomes smooth. As described above, the control voltage VC is equal to the well potential VW, and the relationship between the control voltage VC and the voltage (VG−VW) is a direct function with a negative gradient, and therefore, when the gate potential VG is constant, the capacitance C lowers in response to an increase in the control voltage VC. Hereinafter, this state is referred to as a negative correlation between the control voltage VC and the capacitance C.

The frequency f of the alternating current signal oscillated from the LC-VCO 101 is equal to the resonance frequency of the LC circuit, and this resonance frequency f is determined by the above-mentioned numerical formula 1. Therefore, as shown in FIG. 4, there is a negative correlation between the voltage (VG−VW) to be applied to the varactor elements 9 and 10 and the oscillating frequency f of the LC-VCO 101, and when the voltage (VG−VW) increases, the oscillating frequency f lowers.

However, the above-mentioned prior art has the following problem. FIG. 5 is a graph showing changes in frequency characteristics with respect to changes in power supply potential, wherein the horizontal axis shows the control voltage to be applied to the varactor elements and the vertical axis shows the oscillating frequency of signals to be outputted from the pair of output terminals. As shown in FIG. 5, in the conventional LC-VCO, when the power supply potential Vdd changes, the frequency characteristics, that is, correlation between the oscillating frequency f and the control voltage VC also changes. For example, when the power supply potential Vdd is 1.0V, the characteristics of the LC-VCO are as shown by the solid line, however, when the power supply potential Vdd becomes 0.9V, the characteristics of the LC-VCO shifts to the high frequency side as shown by the dashed line.

To the contrary, when the power supply potential Vdd becomes 1.1V, the characteristics of the LC-VCO shifts to the low frequency side as shown by the alternate long and short dashed line. This characteristic change becomes conspicuous as the control voltage VC becomes higher, and in the conventional LC-VCO, when the power supply potential Vdd changes by ±10%, the oscillating frequency f changes by ±2.5% at maximum although the control voltage VC does not change.

### SUMMARY OF THE INVENTION

An object of the present invention is to provide a voltage control oscillator in which changes in oscillating frequency with respect to changes in power supply potential are small.

A voltage control oscillator according to the present invention comprises an inductor and a varactor element that is connected in parallel to the inductor so as to form a resonance circuit together with the inductor, and the varactor element changes its capacitance according to an inputted control voltage. The varactor element is connected to the inductor so that the capacitance increases when the control voltage increases.

In the present invention, since the varactor element is connected to the inductor so that the capacitance increases when the control voltage increases, the resonance frequency of the resonance circuit can be restrained from changing even when the power supply potential value changes.

Furthermore, the varactor element may have an N type region that is formed on the surface of a substrate, insulated from the rest of the substrate, and connected to the inductor, an insulating film provided on this N type region, and an electrode that is provided on this insulating film and applied with the control voltage.

Or, it is also possible that the varactor element has a P type region that is formed on the surface of the substrate, insulated from the rest of this substrate, and applied with the control voltage, an insulating film provided on this P type region, and an electrode that is provided on this insulating film and connected to the inductor.

Preferably, the voltage control oscillator of the invention further comprises an amplifying part which, when one end of the inductor has a potential higher than that of the other end, applies a first potential to the one end, and applies a second-potential lower than the first potential to the other end.

A voltage control oscillator according to another aspect of the present invention comprises a resonating part that has first and second output terminals and outputs complementary alternating current signals from the first and second output terminals, and an amplifying part which applies a first potential to the first output terminal and applies a second potential to the second output terminal when the potential of the first output terminal is higher than the potential of the second output terminal. The resonating part has an inductor connected between the first and second output terminals, a first varactor element that has one end connected to the first output terminal and the other end that is applied with a control voltage, and changes its capacitance according to the control voltage, and a second varactor element that has one end connected to the second output terminal and the other end that is applied with the control voltage, and changes its capacitance according to the control voltage. The first and second varactor elements are connected to the first and second output terminals so that their capacitance increases when the control voltage increases.

According to the present invention, since varactor elements that form a resonance circuit together with the inductor are connected to the inductor so that the capacitance increases when the control voltage increases, a voltage control oscillator in which changes in oscillating frequency with respect to changes in the first potential are small is realized.

### BRIEF DESCRIPTION OF THE DRAWINGS

FIG. 1 is a circuit diagram showing a conventional LC-VCO;

FIG. 2 is a sectional view showing the varactor element shown in FIG. 1;

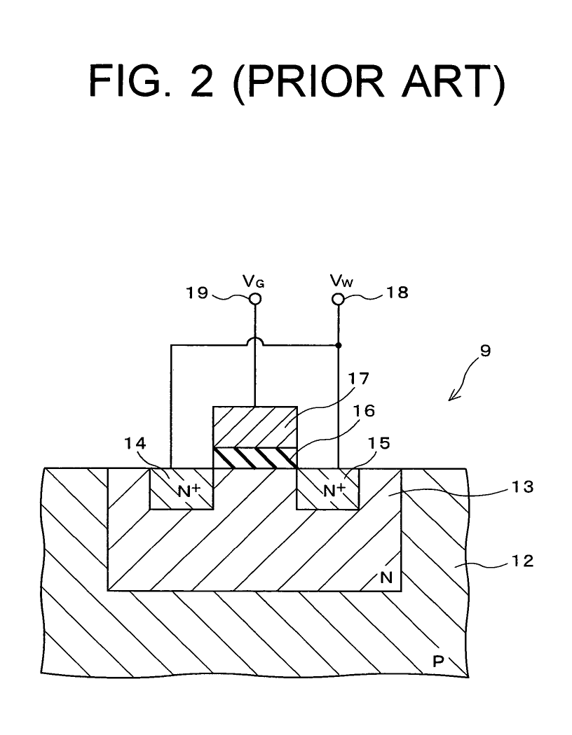

FIG. 3 is a graph showing the characteristics of the varactor element in which the horizontal axis shows the voltage (VG−VW) to be applied to the varactor element and the vertical axis shows the capacitance of this varactor element;

FIG. 4 is a graph showing frequency characteristics of the LC-VCO in which the horizontal axis shows the voltage (VG−VW) to be applied to the varactor element and the vertical axis shows the oscillating frequency of signals to be outputted from the pair of output terminals.

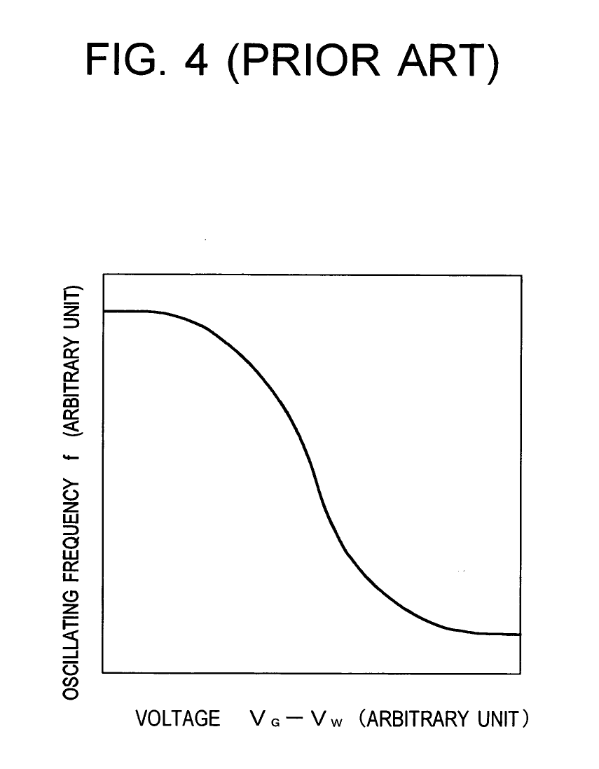

FIG. 5 is a graph showing changes in frequency characteristics with respect to changes in power supply potential in which the horizontal axis shows the control voltage to be applied to the varactor element and the vertical axis shows the oscillating frequency of signals outputted from the pair of output terminals;

FIG. 6 is a circuit diagram showing an LC-VCO of a first embodiment of the invention;

FIG. 7 is a graph showing the characteristics of the varactor element in which the horizontal axis shows the control voltage and the vertical axis shows the capacitance of this varactor element;

FIG. 8 is a graph showing frequency characteristics of the LC-VCO in which the horizontal axis shows the control voltage and the vertical axis shows the oscillating frequency to be outputted from the pair of output terminals;

FIG. 9A and FIG. 9B are diagrams showing the varactor elements and the control terminal of the LC-VCO, wherein FIG. 9A shows the connecting directions of the varactor elements in the conventional LC-VCO, and FIG. 9B shows the connecting directions of the varactor elements in this embodiment;

FIG. 10 is a graph showing changes in capacitance with respect to changes in power supply potential in the conventional LC-VCO in which the horizontal axis shows the voltage to be applied to the varactor element and the vertical axis shows the capacitance of this varactor element;

FIG. 11 is a graph showing changes in capacitance with respect to changes in power supply potential in the LC-VCO of this embodiment in which the horizontal axis shows the voltage to be applied to the varactor element and the vertical axis shows the capacitance of this varactor element; and

FIG. 12 is a sectional view of a varactor element in a second embodiment of the invention.

### DETAILED DESCRIPTION OF THE PREFERRED EMBODIMENTS

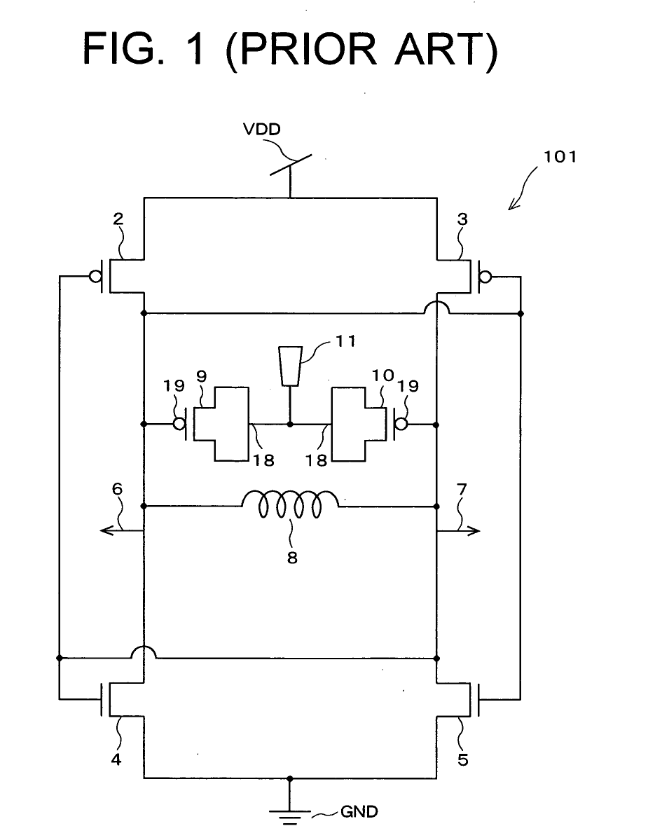

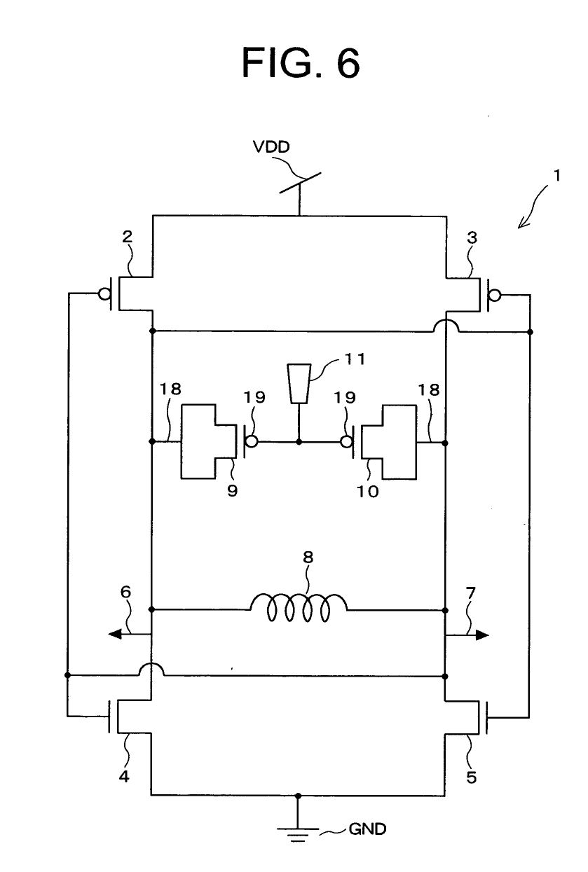

Hereinafter, embodiments of the present invention are described in detail with reference to the accompanying drawings. First, a first embodiment of the present invention is described. FIG. 6 is a circuit diagram showing an LC-VCO relating to the present embodiment. As shown in FIG. 6, in the LC-VCO 1 of the first embodiment, in comparison with the conventional LC-VCO 101 shown in FIG. 1, the connecting directions of the varactor elements 9 and 10 are in reverse. Namely, the well terminals 18 of the varactor elements 9 and 10 are connected to the output terminals 6 and 7, and the gate terminals 19 of the varactor elements 9 and 10 are connected to the control terminal 11.

Other constructional points of the LC-VCO 1 of this embodiment except for the above-described point are the same as those of the above-described conventional LC-VCO 101. Namely, the LC-VCO 1 has a resonating part and an amplifying part. The resonating part outputs complementary alternating current signals from the output terminals 6 and 7, and has an LC circuit including an inductor 8 and varactor elements 9 and 10. The amplifying part applies a power supply potential to the output terminal 6 and applies a ground potential to the output terminal 7 when the potential of the output terminal 6 is higher, that is, at a level higher than the potential level of the output terminal 7, and applies the ground potential to the output terminal 6 and applies the power supply potential to the output terminal 7 when the potential of the output terminal 6 is lower, that is, at a level lower than the potential level of the output terminal 7. The amplifying part includes P type transistors 2 and 3 and N type-transistors 4 and 5. The LC-VCO 1 of this embodiment is used as, for example, a local oscillator of a phase locked loop circuit, and is formed as a part of an integrated circuit on the surface of, for example, a P type silicon substrate.

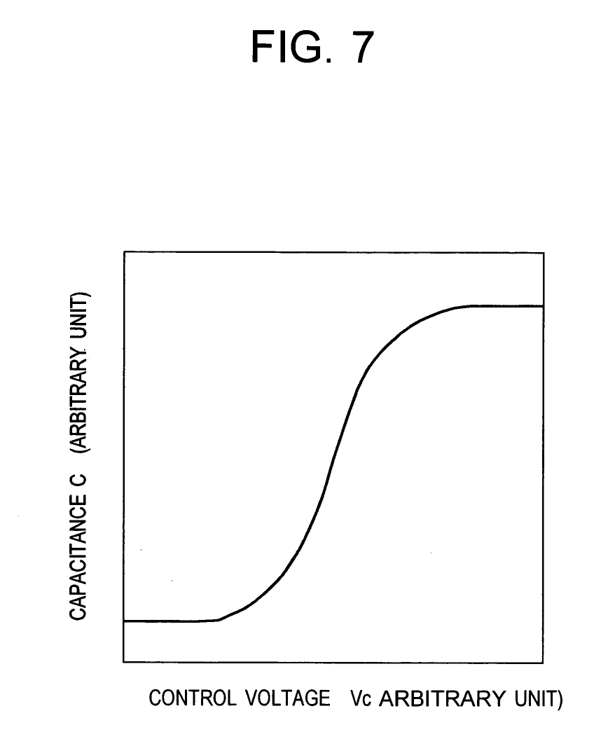

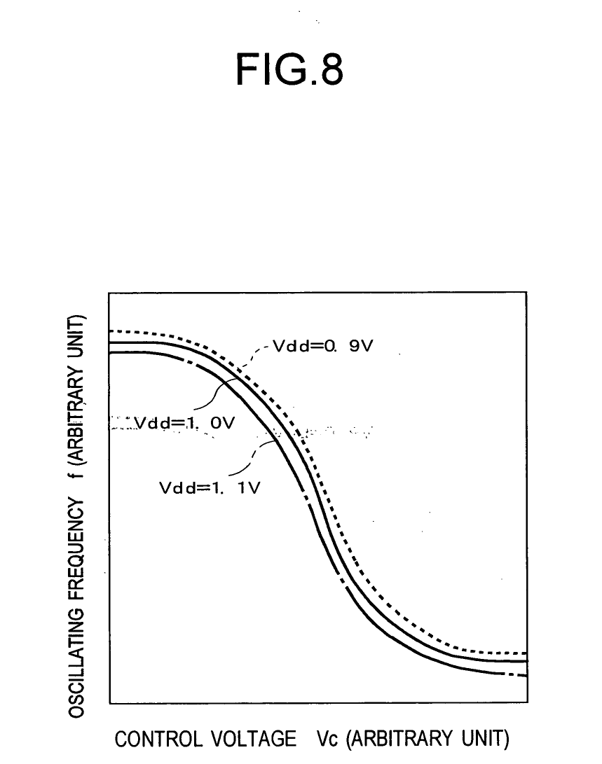

Next, operations of the LC-VCO of the present embodiment constructed as described above are explained. FIG. 7 is a graph showing characteristics of the varactor element in which the horizontal axis shows the control voltage and the vertical axis shows the capacitance of this varactor element, and FIG. 8 is a graph showing frequency characteristics of the LC-VCO in which the horizontal axis shows the control voltage and the vertical axis shows the oscillating frequency of signals outputted from the pair of output terminals. In FIG. 7 and FIG. 8, it is assumed that the well potential VW of the varactor element is constant.

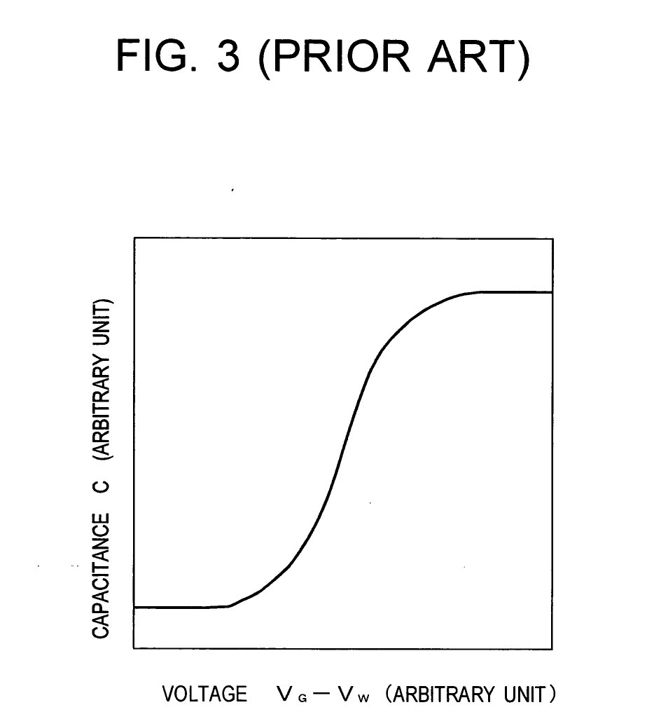

As shown in FIG. 6, in the LC-VCO 1 relating to this embodiment, the control voltage VC is equal to the gate potential VG, so that the relationship between the control voltage VC and the voltage (VG−VW) is a direct function with a positive gradient. As shown in FIG. 3, in the varactor elements 9 and 10, the capacitance C increases when the voltage (VG−VW) increases. Therefore, as shown in FIG. 7, there is a positive correlation between the control voltage VC and the capacitance C, and in the condition where the well potential VW is fixed, when the control voltage VC increases the capacitance C also increases. The increasing rate of the capacitance C with respect to the control voltage VC is high when the control voltage VC is within a predetermined range, and when it is out of the range, the increasing rate becomes small. When the control voltage VC is close to the well potential VW, that is, when the value of the voltage (VG−VW) is close to zero, the increasing rate of the capacitance C becomes high.

The frequency f of alternating current signals oscillated from the LC-VCO 1 is equal to the resonance frequency f of the LC circuit, and this resonance frequency f is determined by the above-described numerical formula 1. Therefore, as shown in FIG. 8, there is a negative correlation between the control voltage VC and the oscillating frequency f of the LC-VCO 1, and when the control voltage VC increases, the oscillating frequency f decreases. Therefore, in the LC-VCO 1, the oscillating frequency f is reduced by increasing the control voltage VC, and the oscillating frequency f is increased by lowering the control voltage VC. Operations other than the operations described above of the LC-VCO 1 of this embodiment are the same as those of the conventional LC-VCO 101 (see FIG. 1).

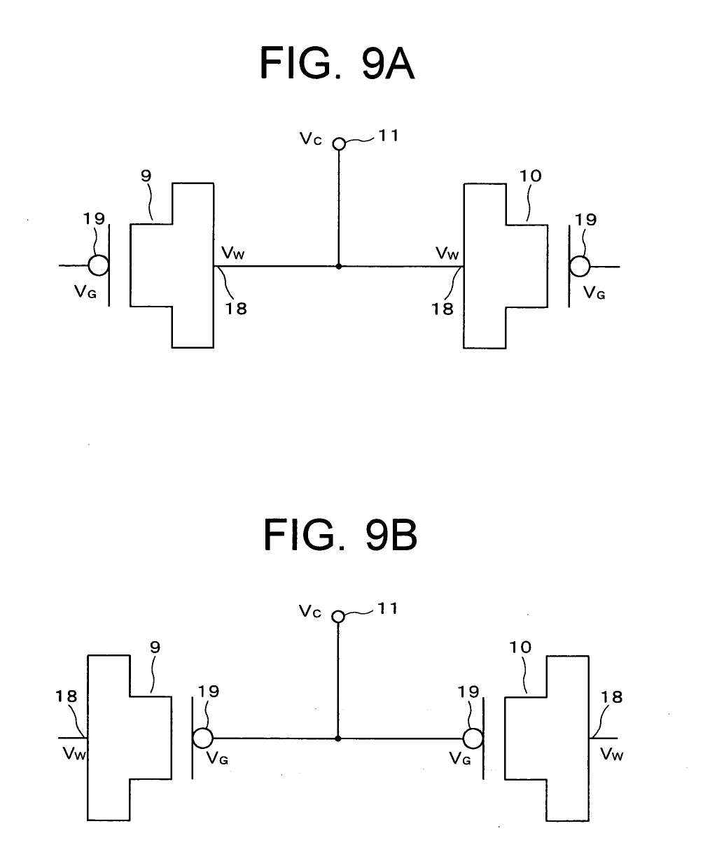

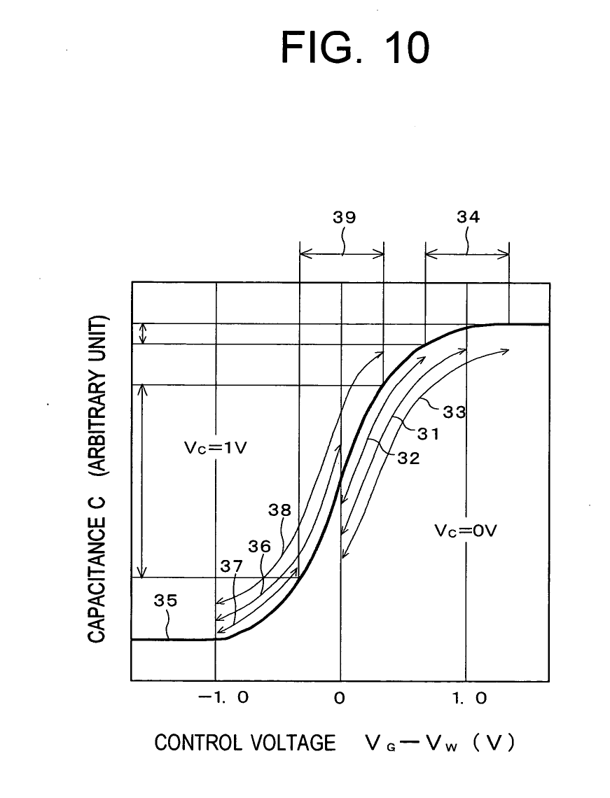

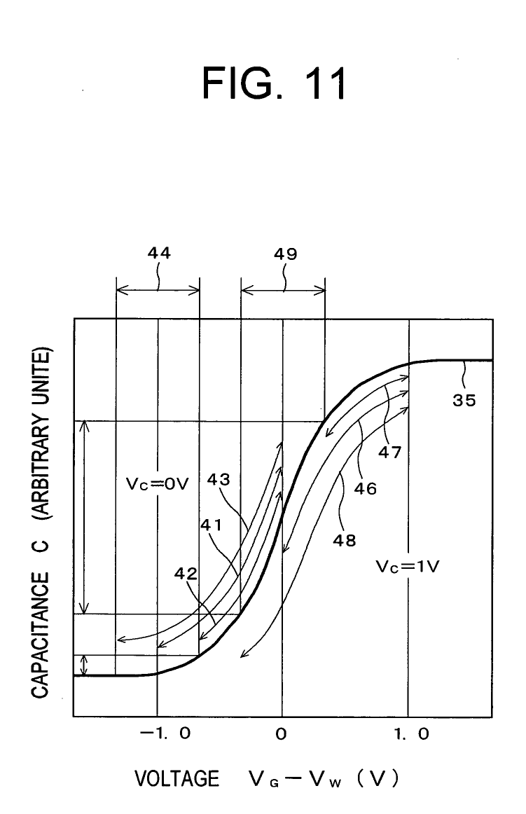

FIG. 9A and FIG. 9B are diagrams showing the varactor elements and the control terminal of the LC-VCO, and FIG. 9A shows the connecting directions of the varactor elements in the conventional LC-VCO, and FIG. 9B shows the connecting directions of the varactor elements in the LC-VCO of this embodiment. FIG. 10 is a graph showing changes in capacitance with respect to changes in power supply potential in the conventional LC-VCO in which the horizontal axis shows the voltage-to be applied to the varactor element and the vertical axis shows the capacitance of this varactor element, and FIG. 11 is a graph showing changes in capacitance with respect to changes in power supply potential in the LC-VCO of this embodiment in which the horizontal axis shows the voltage to be applied to the varactor element and the vertical axis shows the capacitance of this varactor element. The line 35 shown in FIG. 10 and FIG. 11 shows the correlation between the voltage (VG−VW) and the capacitance C. For ease in description, the changes in power supply potential Vdd are shown with exaggeration in FIG. 10 and FIG. 11.

As shown in FIG. 9A, in the conventional LC-VCO, the well terminals 18 of the varactor elements 9 and 10 are connected to the control terminal 11, and the potentials of the output terminals 6 and 7 (see FIG. 1), that is, the potentials that oscillate between the ground potential and the power supply potential are applied to the gate terminals 19. Therefore, as shown in FIG. 10, in the case where the ground potential is 0V and the power supply potential is 1.0V, when the control voltage VC is 0V, the gate potential VG oscillates between the ground potential (0V) and the power supply potential (1.0V), and the well potential VW is equal to the control voltage VC (0V), so that the voltage (VG−VW) oscillates in the range between 0V and 1.0V shown by the arrow 31. Then, when the power supply potential changes to 0.9V, the voltage (VG−VW) oscillates in the range between 0V and 0.9V shown by the arrow 32, and when the power supply potential changes to 1.1V, the voltage (VG−VW) oscillates in the range between 0V and 1.1V shown by the arrow 33. Namely, when the power supply potential changes in the range between 0.9V and 1.1V, the lower limit of the voltage (VG−VW) is 0V and does not change, however, the upper limit changes in the range between 0.9V and 1.1V. Then, since there is a correlation between the voltage (VG−VW) and the capacitance C, when the oscillation range of the voltage (VG−VW) changes, the upper limit of the capacitance C changes although the lower limit does not change, and therefore, the average of the capacitance C changes. However, in the range 34 shown in FIG. 10, the gradient of the line 35 showing the relationship between the voltage (VG−VW) and the capacitance C is slight, so that the amount of change in the average of the capacitance C is small.

When the control voltage VC is 1V, the gate potential VG oscillates between the ground potential (0V) and the power supply potential (1V), and the well potential VW is equal to the control voltage VC (1V), so that the voltage (VG−VW) oscillates in the range between −1V and 0V shown by the arrow 36. Then, when the power supply potential changes to 0.9V, the voltage (VG−VW) oscillates in the range between −1V and −0.1V shown by the arrow 37. When the power supply potential becomes 1.1V, the voltage (VG−VW) oscillates in the range between −1V and +0.1V shown by the arrow 38. Namely, when the power supply potential changes in the range between 0.9V and 1.1V, the lower limit of the voltage (VG−VW) does not change, however, the upper limit changes within the range between −1V and +0.1V. Then, since there is a correlation between the voltage (VG−VW) and the capacitance C, when the oscillation range of the voltage (VG−VW) changes, the upper limit of the capacitance C changes although the lower limit does not change, and therefore, the average of the capacitance C changes. In this case, in the range 39 shown in FIG. 10, the gradient of the line 35 is steep, and the amount of change in the average of the capacitance C is large.

As described above, when the control voltage VC is 0V, the gradient of the line 35 in the range 34 is slight, so that the amount of change in the average of the capacitance C is small. When the control voltage VC is 0V, the absolute value of the capacitance C is comparatively great, and therefore, even when the average of the capacitance C changes, the ratio of change becomes small. Therefore, when the control voltage VC is 0V, the ratio of change (change rate) in the average of the capacitance C with respect to a change in power supply potential becomes extremely small. On the other hand, when the control voltage VC is 1V, the gradient of the line 35 in the range 39 is steep, so that the amount of change in the average of the capacitance C is large. In addition, when the control voltage VC is 1V, the absolute value of the capacitance C is comparatively small, so that when the average of the capacitance C changes, the ratio of change increases. Therefore, when the control voltage VC is 1V, the change rate of the average of the capacitance C with respect to change in power supply potential becomes extremely great.

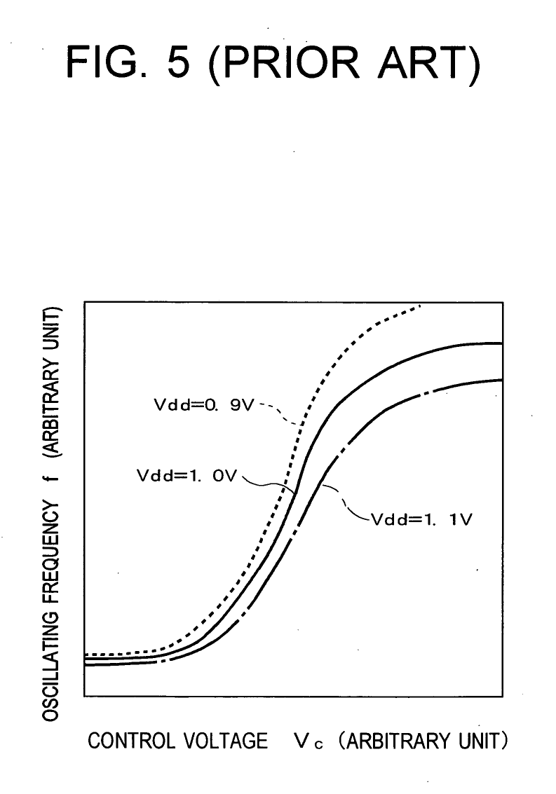

Thus, when the control voltage VC is on the high potential side (for example, 1V), the change rate of the average of the capacitance C becomes extremely great due to dual adverse conditions where the amount of change in the average of the capacitance C is large and the change rate increases due to the small absolute value of the capacitance C even if the amount of change is constant. This change rate in the average of the capacitance C influences the change rate in the oscillating frequency f, and as shown in FIG. 5, the change in oscillating frequency f when the control voltage VC is on the high potential side becomes extremely great.

On the other hand, as shown in FIG. 9B, in the LC-VCO of this embodiment, the gate terminals 19 of the varactor elements 9 and 10 are connected to the control terminal 11, and the potentials of the output terminals 6 and 7 (see FIG. 6), that is, the potentials that oscillate between the ground potential and the power supply potential are applied to the well terminals 18. Therefore, as shown in FIG. 11, in the case where the ground potential is 0V and the power supply potential is 1.0V, when the control voltage VC is 0V, the gate potential VG is equal to the control voltage VC (0V), and the well potential VW oscillates between the ground potential (0V) and the power supply potential (1.0V), so that the voltage (VG−VW) oscillates in the range between −1.0V and 0V shown by the arrow 41. Then, when the power supply potential changes to 0.9V, the voltage (VG−VW) oscillates in the range between −0.9V and 0V shown by the arrow 42, and when the power supply potential becomes 1.1V, the voltage (VG−VW) oscillates in the range between −1.1V and 0V shown by the arrow 43. Namely, when the power supply potential changes in the range between 0.9V and 1.1V, the upper limit of the voltage (VG−VW) is 0V and does not change, however, the lower limit changes within the range 44 between −1.1V and −0.9V. Thereby, although the upper limit of the capacitance C does not change, the lower limit changes, and therefore, the average of the capacitance C changes. However, in the range 44 shown in FIG. 11, the gradient of the line 35 showing the relationship between the voltage (VG−VW) and the capacitance C is slight, so that the amount of change in the average of the capacitance C is small.

When the control voltage VC is 1V, the gate potential VG is equal to the control voltage VC (1V), and the well potential VW oscillates between the ground potential (0V) and the power supply potential (1.0V), so that the voltage (VG−VW) oscillates in the range between 0V and 1.0V shown by the arrow 46. Then, when the power supply potential changes to 0.9V, the voltage (VG−VW) oscillates in the range between +0.1V and 1V shown by the arrow 47, and when the power supply potential becomes 1.1V, the voltage (VG−VW) oscillates in the range between −0.1V and 1.0V shown by the arrow 48. Namely, when the power supply potential changes in the range between 0.9V and 1.1V, the upper limit of the voltage (VG−VW) is 1V and does not change, however, the lower limit changes within the range 49 between −0.1V and +0.1V. Thereby, the lower limit of the capacitance C changes although the upper limit does not change, and therefore, the average of the capacitance C changes. At this point, in the range 49 shown in FIG. 11, the gradient of the line 45 is steep, and the amount of change in the average of the capacitance C is large.

Then, when the control voltage VC is 0V, the absolute value of the capacitance C is comparatively small, so that when the average of the capacitance C changes, the change rate increases. However, as described above, when the control voltage VC is 0V, the gradient of the line 35 in the range 44 is slight, so that the amount of change in the average of the capacitance C is small. Therefore, when the control voltage VC is 0V, the ratio of change in the average of the capacitance C with respect to the change in power supply potential is comparatively small. Furthermore, when the control voltage VC is 1V, as described above, the gradient of the line 35 in the range 49 is steep, so that the amount of change in the average of the capacitance C is large. However, when the control voltage VC is 1V, the absolute value of the capacitance C is comparatively large, and therefore, even when the average of the capacitance C changes, the ratio of change is small. Therefore, even when the control voltage VC is 1V, the change rate of the average of the capacitance C with respect to the change in power supply potential is comparatively small.

As a result, as shown in FIG. 8, in this embodiment, differently from the conventional LC-VCO, whichever the control voltage VC is on the high potential side or the low potential side, adverse conditions where the amount of change in capacitance C is large and the absolute value of the capacitance C is small do not occur simultaneously, and the change rate of the capacitance C does not become extremely great. Therefore, even when the power supply potential Vdd changes, the change in oscillating frequency f can be restrained.

In this embodiment, the change rate of the oscillating frequency f in the case where the power supply potential changes by ±10% is approximately ±1.0% at maximum. This is much smaller than the change rate (±2.5%) of the oscillating frequency f in the conventional LC-VCO. Thus, according to this embodiment, a voltage control oscillator (LC-VCO) in which the change rate of the oscillating frequency is small even when the power supply potential changes can be obtained.

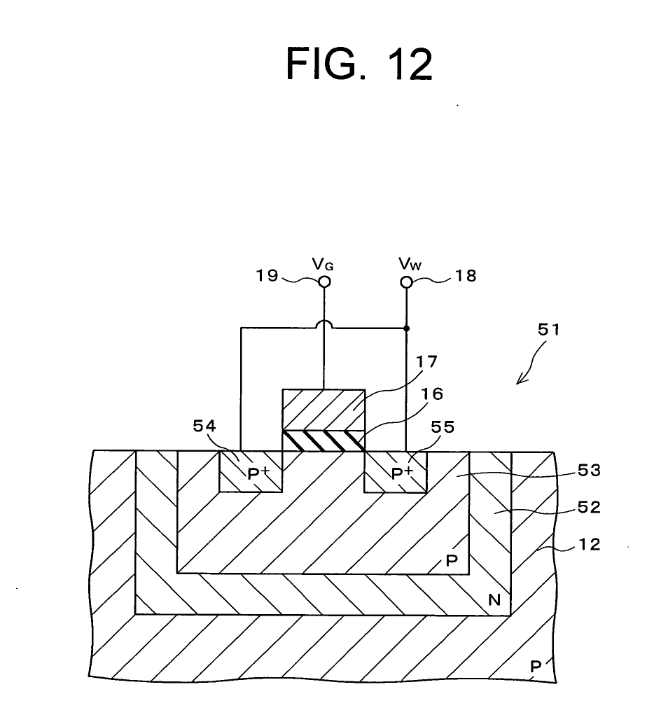

Next, a second embodiment of the invention is described. FIG. 12 is a sectional view showing a varactor element in this embodiment. As shown in FIG. 12, in this embodiment, in comparison with the first embodiment, the construction and connecting direction of the varactor element are different. Namely, in the LC-VCO 1 of the first embodiment shown in FIG. 6, instead of the varactor elements 9 and 10, the varactor elements 51 shown in FIG. 12 are used, respectively. Namely, between the output terminal 6 and the output terminal 7, two varactor elements 51 are connected in series and used. The well terminals 18 of the varactor elements 51 are connected to the control terminal 11, and the gate terminals 19 are connected to the output terminal 6 or 7.

As shown in FIG. 12, in the varactor element 51, an N well 52 is formed on the surface of a P type silicon substrate 12, and on the surface of this N well 52, a P well 53 is formed, and on the surface of this P well 53, P type diffusion regions 54 and 55 are formed apart from each other. At least in the region immediately above the region between the P type diffusion region 54 and the P type diffusion region 55 on the P well 53, a gate insulating film 16 made of, for example, silicon oxide is formed, and on this gate insulating film 16, a gate electrode 17 made of, for example, polysilicon is provided. The P type diffusion regions 54 and 55 are connected to the well terminal 18. The gate electrode 17 is connected to the gate terminal 19. Other constructional points in this embodiment are the same as those of the first embodiment.

Next, operations of the LC-VCO of this embodiment constructed as described above are explained with reference to FIG. 6 and FIG. 12. As described above, the well terminal 18 of the varactor element 51 is connected to the control terminal 11, and the gate terminal 19 is connected to the output terminal 6 or 7. When the control voltage VC to be applied to the control terminal 11 is raised, the well potential VW to be applied to the well terminal 18 becomes high and the gate potential VG with respect to the well potential VW becomes low. Thereby, electron-holes as carriers gather at the region immediately under the gate electrode 17 in the P well 53, and the capacitance between the gate electrode 17 and the P well 53 increases. On the other hand, when the control voltage VC is lowered, the well potential VW becomes low and the gate potential VG with respect to the well potential VW becomes high. Thereby, a depleted layer is formed in the region immediately under the gate electrode 17 in the P well 53, and the capacitance C becomes small.

Thus, like the varactor elements 9 and 10 of the first embodiment, the varactor elements 51 are connected to the output terminals 6 and 7 and the control terminal 11 so that the capacitance C increases when the control voltage VC increases. Namely, the relationship between the control voltage VC and the capacitance C in the varactor element 51 is as shown in FIG. 7. Therefore, the relationship between the voltage (VG−VW) to be applied to the varactor element 51 and the capacitance C and the reaction to changes in power supply potential are as shown in FIG. 11, and the relationship between the control voltage VC and the oscillating frequency f is as shown in FIG. 8. As a result, as in the case of the first embodiment, an LC-VCO in which the oscillating frequency change in response to a change in power supply potential is small can also be realized by this embodiment.

Furthermore, in the first embodiment, between the N well 13 and the silicon substrate 12 shown in FIG. 12, that is, between the well terminals 18 of the varactor elements 9 and 10 shown in FIG. 6 and the ground potential, a parasitic capacitance is generated. Thereby, a parasitic capacitance is generated between the output terminals 6 and 7 having potentials that change at high frequencies and the ground potential, and depending on the conditions, it prevents high-speed operations. On the other hand, in this embodiment, since the gate terminals of the varactor elements 51 are connected to the output terminals 6 and 7, no parasitic capacitance is generated between the output terminals 6 and 7 having potentials that change at high frequencies and the ground potential. Therefore, there is no hindrance in the high speed operations. On the other hand, in the first embodiment, it is not necessary to provide the N well 52 and the P well 53 double in the varactor element as in the case of the second embodiment, and the area for installing the varactor element can be reduced.

1. A voltage control oscillator, comprising:
an inductor;
a varactor element that changes their capacitance according to an inputted control voltage, and is connected in parallel to the inductor so that the capacitance increases when the control voltage increases, thereby forming a resonance circuit together with the inductor.

2. The voltage control oscillator according to claim 1, wherein
the varactor element includes:
an N type region that is formed on the surface of a substrate so as to be insulated from the rest of said substrate, and connected to the inductor;
an insulating film provided on the N type region; and
an electrode which is provided on said insulating film and applied with the control voltage.

3. The voltage control oscillator according to claim 1, wherein
the varactor element includes:
a P type region that is formed on the surface of a substrate so as to be insulated from the rest of said substrate, and applied with the control voltage;
an insulating film provided on said P type region; and
an electrode that is provided on said insulating film and connected to said inductor.

4. The voltage control oscillator according to claim 1, further comprising an amplifying part which, when the potential of one end of said inductor is higher than the potential of the other end thereof, applies a first potential to said one end of said inductor and applies a second potential lower than the first potential to the other end thereof.

5. The voltage control oscillator according to claim 4, wherein the first potential is a power supply potential and the second potential is a ground potential.

6. A voltage control oscillator, comprising:
a resonating part that includes:
first and second output terminals for outputting complementary alternating current signals therefrom,
an inductor connected between the first and second output terminals,
a first varactor element having one terminal connected to the first output terminal and the other terminal that is applied with a control voltage and increases the capacitance when the control voltage increases, and
a second varactor element having one terminal connected to the second output terminal and the other terminal that is applied with the control voltage and increases the capacitance when the control voltage increases; and
an amplifying part which, when the potential of the first output terminal is higher than the potential of the second output terminal, applies a first potential to the first output terminal and applies a second potential lower than the first potential to the second output terminal.

7. The voltage control oscillator according to claim 6, wherein
each of the first and second varactor elements includes:
an N type region that is formed on the surface of a substrate so as to be insulated from the rest of said substrate, and connected to the one terminal of the varactor element;
an insulating film provided on said N type region; and
an electrode that is provided on said insulating film and connected to the other terminal of the varactor element.

8. The voltage control oscillator according to claim 6, wherein
each of the first and second varactor elements includes:
a P type region that is formed on the surface of a substrate so as to be insulated from the rest of said substrate, and connected to the other terminal of the varactor element;
an insulating film provided on said P type region; and
an electrode that is provided on said insulating film and connected to the one terminal of the varactor element.

9. The voltage control oscillator according to claim 6, wherein the first potential is a power supply potential and the second potential is a ground potential.
